(19) United States
(12) Patent Application Publication
(10) Pub. No.: US 2026/0203471 A1
(43) Pub. Date: Jul. 16, 2026

(54) UNIFIED HYBRID MODELING TOOL FOR SYSTEMS OF INTEREST

(71) Applicant: Schlumberger Technology Corporation, Sugar Land, TX (US)

(72) Inventors: Indranil Roychoudhury, Menlo Park, CA (US); Prasham Sheth, Menlo Park, CA (US); Salma Benslimane, Menlo Park, CA (US); Junyi Zou, Sunnyvale, CA (US)

(21) Appl. No.: 18/946,097

(22) Filed: Nov. 13, 2024

(51) Int. Cl. G06F 30/27

(52) U.S. Cl. CPC G06F 30/27

(57) ABSTRACT

Certain aspects of the disclosure provide a method that includes obtaining one or more hybrid modeling frameworks based on a model, each hybrid modeling framework comprising one or more hybrid models; performing triage to select a hybrid modeling framework of the one or more hybrid modeling frameworks that is applicable to the system of interest based on associated metrics and the input data; training each respective hybrid model of the one or more hybrid models of the hybrid modeling framework based on the input data to obtain one or more trained hybrid models configured to model behavior of the system of interest; and determining a rank order of the one or more trained hybrid models based on a benchmark set of data associated with the system of interest.

### BACKGROUND

### Field

Aspects of the present disclosure relate to a hybrid modeling tool for autonomously building, training and testing hybrid models.

### Description of Related Art

Machine learning (ML) models and system models represent two distinct approaches to understanding and predicting systems and phenomena, especially in fields like science, engineering, and economics. ML models are primarily data-driven, learning patterns from large datasets without requiring a predefined understanding of the underlying systems. They exhibit flexibility, capable of adapting to complex, nonlinear relationships, making them well-suited for high-dimensional data. Common types of ML include supervised techniques, unsupervised techniques, and reinforcement learning.

In contrast, system models are grounded in established scientific principles and equations that explain how underlying systems they model operate. These models incorporate physical laws, biological processes, or economic theories, such as differential equations in physics or population dynamics in biology. They offer a high level of predictability, revealing how changes in one part of the system can affect other components based on the underlying mechanisms. Because they are built on known principles, system models are generally more interpretable and easier to explain than ML models that may tend to act like black boxes that are difficult to interpret. As described herein, system models may refer to mechanistic or scientific models that are related to a particular system (scientific models being a broader category that encompass mechanistic models).

Hybrid modeling refers to the combination of ML models and system models (e.g., mechanistic models) to leverage the strengths of each approach. By integrating data-driven techniques with theory-based frameworks, hybrid models can provide more robust predictions and deeper insights into complex systems. Hybrid modeling is well-suited, due to its approach of combining theory-based models with data, for the simulation of complex physical processes with simple model structures and low computational complexity. Hybrid modeling has become an important technology in various fields of research and industry. This type of modeling is deployed in several domains including engineering and scientific computing, industrial processes, artificial intelligence (AI) and machine learning (ML), environmental science (where it can combine ecological models with data-driven approaches), as well as healthcare.

### SUMMARY

One aspect provides a method of obtaining one or more hybrid modeling frameworks based on the model, each hybrid modeling framework comprising one or more hybrid models; performing triage to select a hybrid modeling framework of the one or more hybrid modeling frameworks that is applicable to the system of interest based on associated metrics and the input data; training each respective hybrid model of the one or more hybrid models of the hybrid modeling framework based on the input data to obtain one or more trained hybrid models configured to model behavior of the system of interest; and determining a rank order of the one or more trained hybrid models based on a benchmark set of data associated with the system of interest.

Other aspects provide processing systems configured to perform the aforementioned methods as well as those described herein; non-transitory, computer-readable media comprising instructions that, when executed by a processors of a processing system, cause the processing system to perform the aforementioned methods as well as those described herein; a computer program product embodied on a computer readable storage medium comprising code for performing the aforementioned methods as well as those further described herein; and a processing system comprising means for performing the aforementioned methods as well as those further described herein.

The following description and the related drawings set forth in detail certain illustrative features of one or more aspects.

### DESCRIPTION OF THE DRAWINGS

The appended figures depict certain aspects and are therefore not to be considered limiting of the scope of this disclosure.

FIG. 1 depicts an example system deploying a hybrid modeling tool.

FIG. 2 depicts an example table detailing types of frameworks to generate hybrid models.

FIG. 3 depicts an example triage process of the modeling tool.

FIG. 4 depicts an example architecture of a discrete time state-space model.

FIG. 5 depicts an example architecture of a parameter closure learning framework.

FIG. 6 depicts an example architecture of a state closure learning framework.

FIG. 7 depicts an example architecture of an output closure learning framework.

FIG. 8 depicts an example architecture for a mechanistic neural ordinary differential equation (ODE) framework.

FIG. 9 depicts an example black-box neural ODE framework.

FIG. 10A depicts an example triage process for hybrid modeling by the hybrid modeling tool.

FIG. 10B depicts an example training process for hybrid modeling by the hybrid modeling tool.

FIG. 10C depicts example model ranking process for hybrid modeling by the hybrid modeling tool.

FIG. 11 depicts an example of a method performed by a processing system.

FIG. 12 depicts an example processing system with which aspects of the present disclosure can be performed.

To facilitate understanding, identical reference numerals have been used, where possible, to designate identical elements that are common to the drawings. It is contemplated that elements and features of one embodiment may be beneficially incorporated in other embodiments without further recitation.

### DETAILED DESCRIPTION

Aspects of the present disclosure provide apparatuses, methods, processing systems, and computer-readable mediums for a hybrid modeling tool for autonomously building, training and testing hybrid models.

ML models are generally data-driven, which means the validity of the outputs heavily depend on the validity of the inputs used. ML models therefore cannot guarantee the scientific validity of their outputs, which rely heavily on the validity of their inputs.

System models (e.g., mechanistic or scientific models) rely on the underlying theories related to the system of concern. A system model aims to mimic a system through its assumptions on the underlying mechanisms of the system. This may involve constructing mathematical formulations representing those physical systems and determining whether the input or output behaviors of the model is consistent with experimental or scientific data. System models are therefore generally specific to a domain or physical system making them inflexible in their application. Due to their complexity, system models tend to be compute resource intensive.

Industries in different fields utilize different underlying systems. For example, in healthcare, anatomical and biochemical systems may be of most concern. In the oil and gas industry it may be that reservoir and seismic systems are the most relevant. System models may exist for a particular physical system, but these models are generally inflexible and may rely on the availability of domain experts for their use. Hybrid models that combine the benefits of ML models with system models may be created specifically for each system or industry. However, creating each hybrid model on a bespoke basis is time consuming and computationally resource intensive. Furthermore, without a common framework, generated hybrid models may vary in their validity and reliability.

Aspects described herein present a hybrid modeling tool that provides a streamlined and automated process of building, training, and testing hybrid models. The modeling tool may utilize a discrete-time state-space modeling framework that may be deploy various models of various types as a hybrid model to be readily applied to any dynamical system of interest (e.g., a physical system) given a set of inductive biases. A technical benefit of the hybrid modeling tool is the ability to generate hybrid models that utilize expressions of ML techniques, inductive bias from system models, and signals from underlying data to arrive at a hybrid model for a physical system of interest.

Generating hybrid models may involve multiple computational demands across development, integration, validation, and performance evaluation stages. For example, at the model development stage, selecting the appropriate algorithms for each component of the hybrid model often involves testing several models. This can require substantial computational resources for simulations and evaluations. Additionally, the process of optimizing parameters for different model components typically requires numerous iterations, which can be computationally expensive.

The aspects described herein provide modeling tools and processes for autonomous hybrid model generation that may be applied to a wide range of systems, and which beneficially reduce compute resource usage compared to manually generating hybrid models. For example, the modeling tool may autonomously classify hybrid modeling algorithms into various frameworks, and may automatically perform processes to select the types of algorithms and models to utilize in the generated hybrid model based on the data available. For example, the modeling tools and processes described utilize a specialized triage process that autonomously selects from several types of hybrid modeling framework(s) (referred to herein as framework(s)) based on underlying system model(s) and input data to generate hybrid model(s). The triage process to select the framework(s) reduces the amount of testing that may be expended and reduces computational resources dedicated for simulations and evaluations.

In certain aspects of hybrid modeling, an integration phase may attempt to ensure that different model components work together. This phase may require additional computations and processing to align data formats, scales, and structures. There may also be multiple rounds of simulations to understand how the various components of the models interact with each round of simulation, this also being computationally resource intensive (e.g., requiring a high amount of compute and memory). Therefore, generating new hybrid models may include an integration phase that relies on computationally intensive processes, which makes custom bespoke hybrid model generation for each type of industry or system difficult.

The modeling tool described herein and its associated processes rely on pre-designed model combinations that may be applied in various contexts based on specific hybrid modeling framework(s). The hybrid modeling tool therefore provides for components of model combinations that are known to be integrate well with each other, reducing any processing or computations to determine integration of models together.

In certain aspects, implementation of hybrids models may also present challenges. For example, using multiple software packages to build and test a hybrid model, may present high computational overhead from data transfers and compatibility synchronizations that adds both computational resource use and computational time.

The use of a unified modeling tool to build and test hybrid models reduces overhead from data transfers or data transformations between different software packages or tools. A unified modeling tool therefore simplifies the process and reduces computational time and computational resources in generating hybrid models.

### Example Hybrid Modeling Tool Systems and Processes

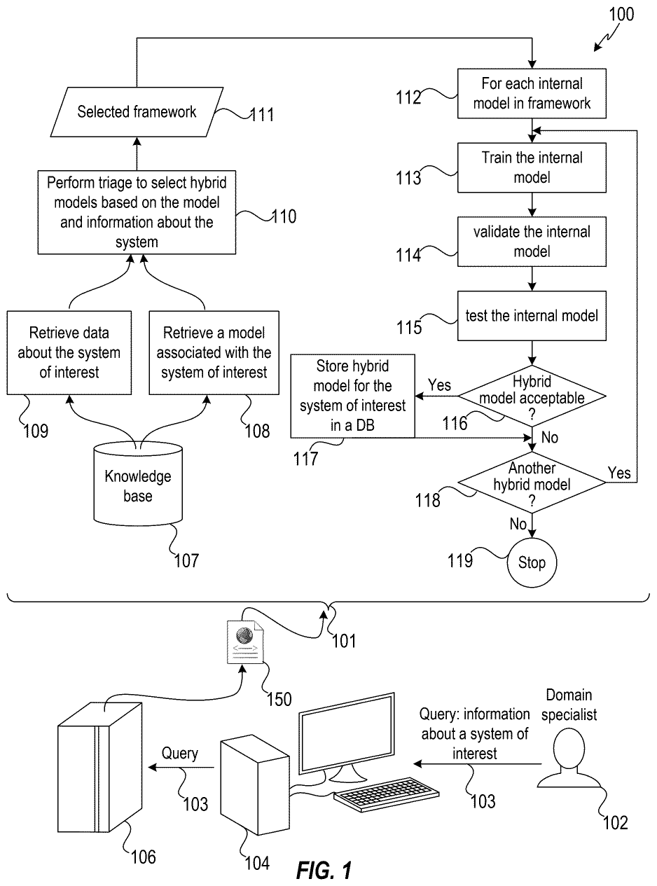

FIG. 1 depicts an example system 100 deploying a hybrid modeling tool 150 (modeling tool 150) that can execute a modeling tool process 101. The modeling tool 150 may be software-based, and may be comprised of any one or more of applications, applets, integrated developmental environments, software libraries, data sources and the like. The system 100 may include a user device 104, which may be any sort of computing device, including desktop, tablet, and mobile computing devices. The user device 104 may contain or be connected to a display. A user 102, e.g., a domain specialist, may input a query 103 into the user device 104. For example, the user device 104 may display a user interface (UI) that enables the user 102 to input data. For example, the query 103 may initiate the modeling tool process 101. In some aspects, the query 103 may be information or input data about a system of interest. For example, the user 102 may select, e.g., on a user interface (UI), a specific system or type of system, e.g., a system of interest, to model with the modeling tool process 101.

The query 103 is sent to a server system 106. The server system 106 may be a single server, a combination of servers, mainframe, an on-premises server system, a cloud-based server system, an OS type of server or other specialized server(s) (e.g., virtual servers). In some aspects, the server system 106 triggers the modeling tool 150 to initiate the modeling tool process 101. The modeling tool process 101 may include obtaining data from a knowledge base 107, which may comprise any type of a centralized repository of information, e.g., internal organizational databases or documentation platforms.

At 108 the modeling tool process 101 includes obtaining a system model associated with the system of interest. The system model may represent the system of interest for which a hybrid model is to be generated. For example, the system model may include representations of a physical system of interest with equations. The system model may be of various levels of abstraction, including black-box models, causal-directed acyclic graphs, functional models, and realized models (in order from highest level of abstraction to lowest level of abstraction). In some aspects, the system model at 108 is selected by the user 102 or is otherwise triggered by the query 103. The system model retrieved at 108 may be a mechanistic model, statistical model, a physical environmental model, physics model, or other scientific model.

The modeling tool 150 can also obtain data at 109 (e.g., input data) about the system of interest from the knowledge base 107. The modeling tool 150 may also obtain data about the system of interest from a user input, e.g., from the query 103, or from the knowledge base 107 based on the user input. For example, if the system of interest was a natural gas reservoir, then the data may include chemical reaction modeling data. The data obtained at 109 may be based on official data, e.g., organizational or governmental published data. In some aspects, 108 or 109 may be associated with or triggered by the query 103. For example, the user 102 may input the query 103 to retrieve the data at 109 or to retrieve the model at 108. In some aspects, the query 103 itself may include data inputs (e.g., data on a particular reservoir or the particular system) from the user 102 that are sent to the knowledge base 107 or to the modeling tool 150.

At 110, the modeling tool 150 performs a triage to select framework(s) 111 associated with the system model obtained at 108. The triage at 110 may include eliminating other framework(s) not suitable for hybrid modeling based on the system model from 108, the data from 109, or both. The selected framework(s) 111 may comprise hybrid model(s) 112. The hybrid model(s) 112 may comprise various models of varying types combined within the framework.

In some aspects, the framework(s) 111 may have their association(s) with the system model preconfigured in the knowledge base 107. The framework(s) 111 provide hybrid model(s) comprising any number of combinations of various models, e.g., a combination of a system model and a data-driven model (e.g., mechanistic model(s) and ML model(s)). In some aspects, framework(s) comprise hybrid model(s) of a combination of physics-based models and data-driven models (e.g., ML model).

The modeling tool 150 may train the hybrid model(s) 112 of the framework(s) 111 at 113. Training the hybrid model(s) 112 at 113 may include training an ML model of the hybrid model(s) 112 using a dataset, e.g., the data retrieved at 109. During training, the hybrid model(s) 112 may learn patterns and relationships between the data and the various models within the hybrid model(s) 112 by adjusting its parameters to minimize the difference between its predictions and labeled data, such as the actual outcomes.

At 114 validating the hybrid model(s) 112 may include further tuning the model, e.g., tuning its hyperparameters, by using a different dataset to the training dataset used at 113. Validation is performed at 114 to help prevent overfitting so that the hybrid model(s) 112 can be applied to a wide-range of data sets and contexts.

At 115, the modeling tool 150 may test the hybrid model(s) 112. This may include evaluating the hybrid model(s) 112 on a test data set which may be a second data set obtained at 109 or otherwise obtained by the modeling tool 150. Testing the hybrid model(s) 112 assesses how well the hybrid model(s) 112 generalizes to new, unseen data, providing an estimate of its performance in real-world scenarios.

Based on the results of 113-115, the modeling tool 150 makes a determination at 116 on whether the now trained, tested, and validated hybrid model(s) 112 are acceptable. This determination may be based on pre-defined performance metrics of outputs of the hybrid model(s) 112. The benchmarks may be associated with the framework(s) 111 to determine if the hybrid model(s) are performant. If the hybrid model(s) 112 meet pre-defined benchmark(s), at 117 they may be stored in a database, e.g., for future use by the modeling tool 150.

At 118, the modeling tool 150 may determine whether additional hybrid model(s) 112 should be trained. The number of hybrid model(s) 112 may be based on a configuration of the user 102 or obtained as part of the query 103, or be associated with the framework(s) 111. For example, each of the framework(s) 111 may set a certain number of hybrid model(s) 112 to be trained when the framework(s) 111 is selected. If the modeling tool 150 determines at 117 that additional hybrid model(s) 112 should be trained, then 113-115 are applied to other hybrid model(s) 112.

The modeling tool process 101 may stop at 119, if the modeling tool 150 determines at 118 that a sufficient number of acceptable hybrid models have been generated.

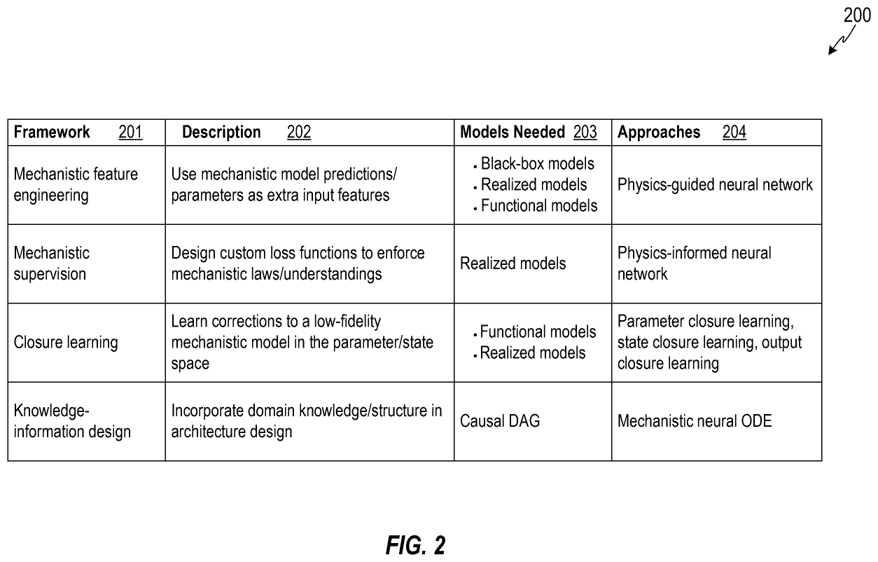

FIG. 2 depicts an example table 200 detailing types of frameworks for hybrid modeling tool to generate hybrid model(s). The column 201 describes the framework(s) that may be used by the modeling tool to generate hybrid models for a system of interest. The modeling tool may correspond to the modeling tool 150 of FIG. 1 and its processes, e.g., the modeling tool process 101 of FIG. 1. The framework(s) in the column 201 may correspond to the framework(s) 111 of FIG. 1. Example hybrid model(s) listed in the column 201 include a mechanistic feature engineering framework, a mechanistic supervision framework, a closure learning framework, and a knowledge-information design framework, and may correspond to the hybrid model(s) 112 of FIG. 1. The example table 200 may involve data that is hardcoded into the modeling tool.

The example table 200 also includes a column 202 describing corresponding framework(s) of the column 201. For example, based on the column 202, the mechanistic feature engineering framework relies on mechanistic model predictions or parameters as extra input features to its hybrid model(s). The mechanistic supervision framework uses custom loss functions for enforcing mechanistic or scientific laws or phenomenon understandings on its internal models. The closure learning framework learns corrections to low-fidelity mechanistic model(s) in a parameter/state-space. Finally, the knowledge-information design framework incorporates domain knowledge or structures in its design.

The example table 200 also includes a column 203 listing system models that may be utilized by corresponding frameworks in the column 201. These system models may be of different levels of abstraction. Listed from highest to lowest levels of abstraction, the mechanistic models can include black-box models, causal-directed acyclic graphs, functional models, and realized models. These mechanistic models can be inputs to the modeling tool to determine the appropriate framework(s) during a triage process, e.g., 110 of FIG. 1. The system models listed in the column 203 may correspond to the system model obtained at 108 of FIG. 1.

For example, based on the column 203, the mechanistic feature engineering framework may utilize black box models, realized models, and functional models. The mechanistic supervision framework only uses realized models. The closure learning framework uses both functional models and realized models. The knowledge-information design only uses causal DAGs.

Column 204 lists possible approaches that may be taken by each of the frameworks of the column 201. The mechanistic feature engineering framework may be a physics-guided neural network. The mechanistic supervision framework may be a physics-informed neural network. The closure learning framework may utilize any of parameter closure learning, state closure learning, or output closure learning. The knowledge-information design framework may utilize mechanistic neural ODE.

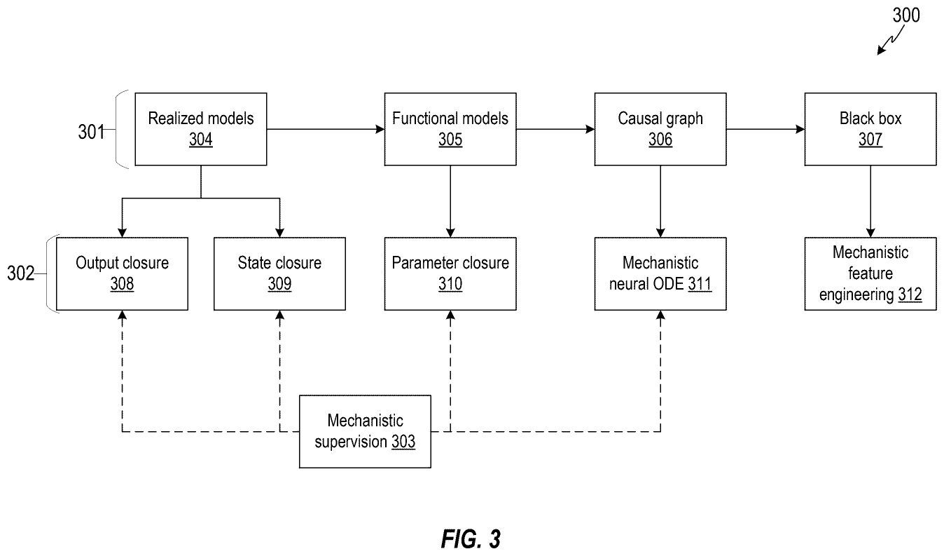

FIG. 3 depicts an example triage process 300 of the modeling tool. The triage 300 may correspond with the triage at 110 of FIG. 1. The triage 300 is a determination of what hybrid model framework(s) 302 to use based on the available system models, e.g., the system model(s) obtained at 108 of FIG. 1. The modeling tool may correspond with the modeling tool 150 of FIG. 1 The framework(s) 302 may correspond with the framework(s) 111 of FIG. 1, or the framework(s) listed in the column 201 of FIG. 2.

System models 301 may include models of varying levels of abstraction. The system models 301 may correspond to the models listed in the column 203 of FIG. 2. The system models 301 may include a realized model 304, a functional model 305, a causal graph model 306, and a black box model 307 (listed in order of lowest abstraction to highest abstraction). A realized model 304 may be a model where the functions have parameters with given values. A functional model 305 may define some relationships between inputs and outputs functionally, e.g., outputs defined with functions based on parameters. A causal graph model 306 is a model where some inputs are connected to some outputs through causal relationships, but the calculations or transformation of inputs to outputs are otherwise unknown or unobservable. A black box model 307 may be a model where inputs are processed in an unobservable algorithm that transforms them into outputs, and where only the inputs and outputs may be observed without any relationships between them.

The framework(s) 302 may include an output closure framework 308, a state closure framework 309, a parameter closure framework 310, a mechanistic neural ODE framework 311, and a mechanistic feature engineering framework 312. The triage 300 determines which framework(s) 302 to implement based on available system models 301 for the system under consideration. For example, if a realized model 304 is available, then available framework(s) 302 may include the output closure framework 308 or the state closure framework 309. In aspects, where a functional model 305 is available, the framework(s) 302 deployed may include the parameter closure framework 310. In aspects where a causal graph model 306 is available to the modeling tool, the mechanistic neural ODE framework 311 may be deployed. In aspects where a black box model 307 is available to the modeling tool, the mechanistic feature engineering framework 312 may be used.

In some aspects of the triage 300, given the availability of a type of the system models 320, the modeling tool can also derive other model types of higher abstraction (e.g., models requiring less detail). For example, if a realized model 304 is available, the modeling tool may derive any of the other system models 305-307, and consequently may use any of the frameworks suitable for the other models. However, if a black box model 307 is available (model with the highest abstraction) then other models cannot be derived from it. The rules of the triage 300 may be hard coded into a catalogue or look-up table, for example in the knowledge base 107, of FIG. 1, with data similar to the example table 200 of FIG. 2.

In some aspects, The output closure framework 308, the state closure framework 309, the parameter closure framework 310 and the mechanistic neural ODE framework 311 may rely on a mechanistic supervision 303, where the frameworks 308-311 rely on mechanistic supervision 303 to enforce mechanistic laws/understandings for their respective models. Mechanistic supervision refers to a system model (e.g., a state transition model) supervising or inputting parameters into a neural network to reinforce or adjust its learning.

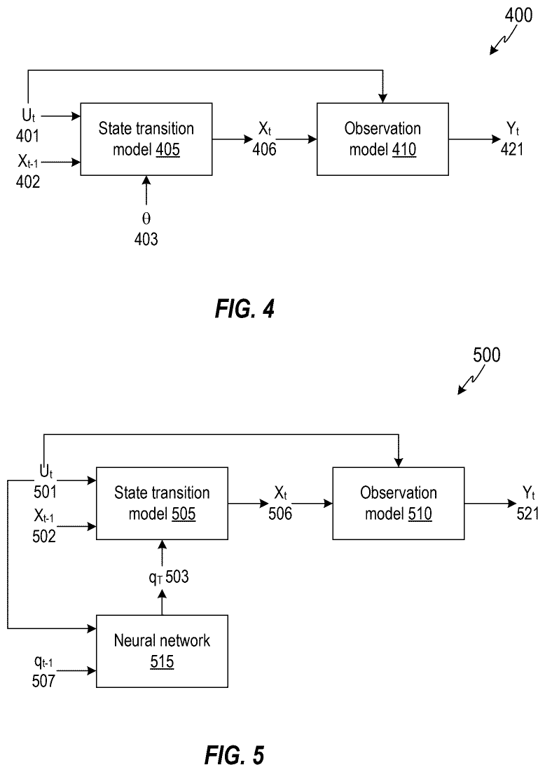

FIG. 4 depicts an example architecture of a state-space model 400 that may be applied in various hybrid modeling framework(s) to generate a hybrid model. The example architecture may be one example of an architecture of any of the framework(s) 302 of FIG. 3, of the framework(s) listed in column 201 of FIG. 2, or of the framework(s) 111 of FIG. 1 for generating a hybrid model. The final output (Yₜ) 421 generated by the state-space model 400 may represent an underlying data generating system, e.g., a state of a system of interest being modeled by the hybrid model.

The primary components of the state-space model 400 include a state-transition model 405 (which may be a system model) and an observation model 410. The state-space model 400 may be described by the following two example equations:

$${X}_{t} = g ( {X}_{t - 1} , {U}_{t} ; θ ) \qquad Eq . 4.1$$

$${Y}_{t} = h ( {X}_{t} , {U}_{t} ) \qquad Eq . 4.2$$

Function (g) represents state-transition model 405. Equation 4.0 represents function (g) producing an output of a latent state (Xₜ) 406 of the state-transition model 405. Function (h) represents the observation model 410. The Equation 4.1 represents function (h) producing the final output (Yₜ) 421 using the latent state (Xₜ) 406 output of Equation 4.0 as input into function (h) of Equation 4.1.

Exogenous input(s) (Uₜ) 401 represent inputs at discrete time step (t). The exogenous input(s) (Uₜ) 401 may correspond with the data obtained at 109 of FIG. 1 or it may correspond with data received via the query 103 of FIG. 1. Function (g), with model parameters (θ) 403 represents the evolution of the latent state (Xₜ) 406 over time under the influence of the exogenous input(s) (Uₜ) 401. The prior state input(s) (Xₜ₋₁) 402 represents a prior state of the state-transition model at discrete time step (t-1) which is input into the function (g) to generate the state-transition model 405's latent state (Xₜ) 406. The prior state input(s) (Xₜ₋₁) 402 may correspond with the system model obtained at 108 of FIG. 1 or with data received via the query 103 of FIG. 1. Latent state (Xₜ) 406 is an output generated by the function (g) and represents the state-transition model 405's latent state (Xₜ) 406 at time (t).

Function (h) represents the observation model 410. Function (h) represents how the output (Yₜ) 411 is generated from the latent state (Xₜ) 406 used as an input with the exogenous input(s) (Uₜ) 401. Function (h) produces the final output (Yₜ) 421, which represents measured outputs at time (t) based on its inputs 401 and 406.

Model parameters (θ) 403 represents model parameters and may be predefined by a system model, e.g., the system models 301 of FIG. 3 or those listed in the column 203 of FIG. 2. The model parameters may be for a system model that corresponds to the system model obtained at 108 of FIG. 1.

In certain aspects, for data-driven models, both functions (g) and (h) may comprise black-box deep neural networks. And for system models (e.g., mechanistic models), both (g) and (h) may comprise explicit functional forms. Generating a hybrid model includes combining deep neural networks and system models when deciding (g) and (h) based on the framework(s) utilized (e.g., the framework(s) 302 of FIG. 3).

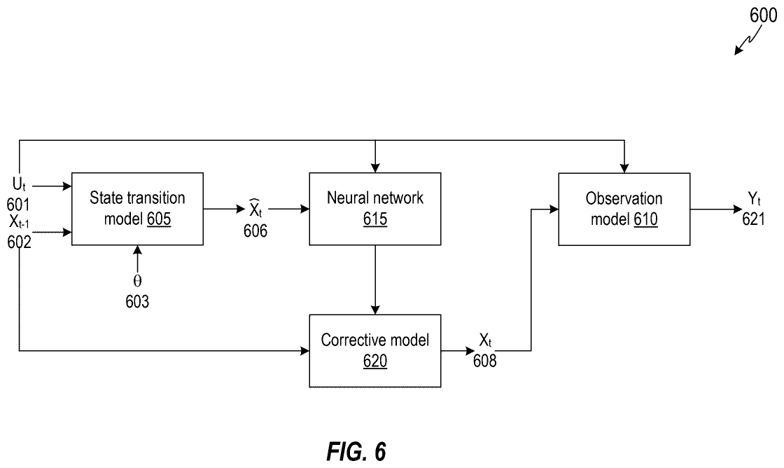

FIG. 5 depicts an example architecture of a parameter closure framework 500. The parameter closure framework 500 may correspond to the parameter closure framework 310 of FIG. 3. The parameter closure framework 500 comprises a state-transition model 505, an observation model 510, and a neural network 515. The neural network 515 may represent any deep neural network that maps a real vector to another vector of possibly different length. The parameter closure framework 500 may be applied when functional models are available, e.g., the functional model 305 of FIG. 3. The final output (Yₜ) 521 generated by parameter closure framework 500 may represent an underlying data generating system, e.g., a state of a system of interest being modeled by hybrid model.

In some aspects, system models (e.g., mechanistic models) assume parameters to be fixed. The parameter closure framework 500 allows parameters to change over time which provides flexibility to the hybrid model(s) generated. In certain cases, changing parameters also better represent the underlying data-generating mechanisms (to better represent phenomenon such as equipment aging, or environmental changes over time). The parameter closure framework 500 may be represented by the following equations:

$${θ}_{t} = NN ( {θ}_{t - 1} , {X}_{t - 1} , {U}_{t} ) \qquad Eq . 5.$$

$${X}_{t} = {g}_{0} ( {X}_{t - 1} , {U}_{t} ; {θ}_{\underline{t}} ) \qquad Eq . 5.1$$

$${Y}_{t} = {h}_{0} ( {X}_{t} , {U}_{t} ) \qquad Eq . 5.2$$

### Where:

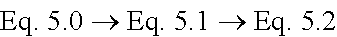

The functions (g₀) and (h₀) represent functions used by system models, where function (g₀) represents the state-transition model 505 and function (h₀) represents the observation model 510. The function (NN) represents the neural network 515. Equation 5.1 represents function (g₀) producing an output of a latent state (Xₜ) 506 of the state-transition model 505. The Equation 5.2 represents function (h₀) producing the final output (Yₜ) 521 using the latent state (Xₜ) 506 as an input. Equation 5.0 represents function (NN) producing an output model parameter (θt) 503 that is input into the function (g₀) of Equation 5.1.

Exogenous input(s) (Uₜ) 501 represent inputs at discrete time step (t). The exogenous input(s) (Uₜ) 501 may correspond with the data obtained at 109 of FIG. 1 or it may correspond with data received via the query 103 of FIG. 1. Function (g₀) with model parameters (θₜ) 503 represents the evolution of the latent state (Xₜ) 506 over time under the influence of the exogenous input(s) (Uₜ) 501. The prior state input(s) (Xₜ₋₁) 502 represents a prior state of the state-transition model 505 at discrete time step (t-1). The prior state input(s) (Xₜ₋₁) 502 is input into the function (g₀) to generate the state-transition model 505 latent state (Xₜ) 506. The prior state input(s) (Xₜ₋₁) 502 may correspond with the system model obtained at 108 of FIG. 1 or with data received via the query 103 of FIG. 1.

Function (h₀) represents the observation model 510. Function (h₀) represents how the observable output is generated from the latent state (Xₜ) 506 as well as the exogenous input(s) (Uₜ) 501. Function (h₀) produces the output (Yₜ) 511, which represents measured outputs at time t based on its inputs 501 and 506.

Model parameter(s) (θₜ) 503 represents model parameters at time (t) and may be predefined by a system model, e.g., the system models 301 of FIG. 3 or those listed in 203 of FIG. 2. The model parameters may be for a system model that corresponds to the system model obtained at 108 of FIG. 1. In the parameter closure framework 500, the model parameters (θₜ) 503 may be updated by the neural network 515 and may be outputs of the neural network 515. The inputs to the neural network 515 may be the prior parameters (θₜ₋₁) 507 of a previous time step (t-1), which then outputs the model parameters (θₜ) 503 for a time step (t). In some aspects, the outputs of the model parameter(s) (θₜ) 503 of the neural network 515 are inputs to the state-transition model 505 which produces an output of latent state (Xₜ) 506 to be an input into the observation model 510 as represented by the function (h₀). The observation model 510 then generates the output (Yₜ) 511 from the input of the latent state (Xₜ) 506.

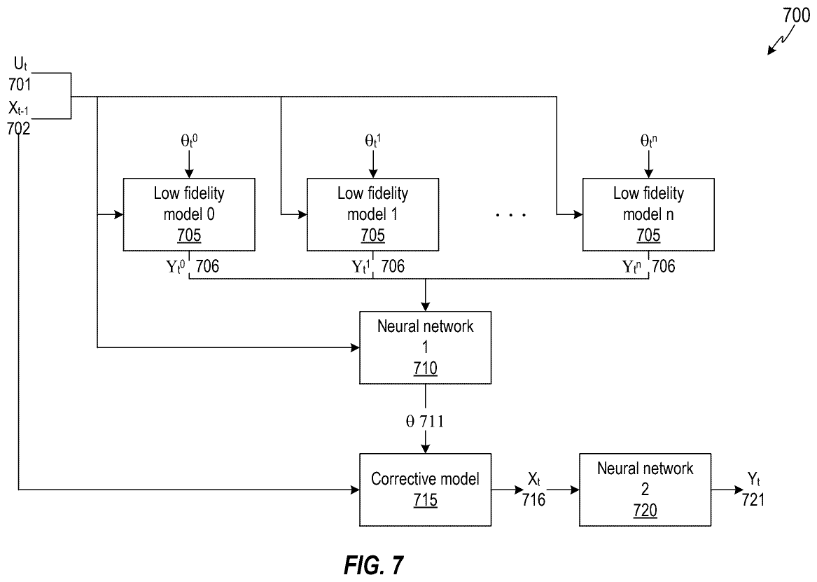

FIG. 6 depicts an example architecture of a state closure framework 600. The state closure framework 600 may correspond to the state closure framework 309 of FIG. 3. The state closure framework 600 comprises a state-transition model 605, an observation model 610, a neural network 615, and a corrective model 620. The neural network 615 may represent any deep neural network that maps a real vector to another vector of possibly different length. The state closure framework 600 may be applied to realized models, e.g., the realized model 304 of FIG. 3. The final output (Yₜ) 621 generated by the state closure framework 600 may represent an underlying data generating system, e.g., a state of a system of interest being modeled by the hybrid model.

The state closure framework 600 is used on the assumption that parameter learning on its own, e.g., as is done in the parameter closure framework 500 of FIG. 5, is not sufficiently accurate and requires corrections from a neural network at each time step to prevent error accumulation and to enhance stability. One example of the state closure framework 600 is represented by the following equations:

$${\hat{X}}_{\underline{t}} = {g}_{0} ( {X}_{t - 1} , {U}_{t} ; θ ) \qquad Eq . 6.$$

$${X}_{t} = {X}_{t - 1 +} N N ( {\hat{X}}_{t} , {U}_{t} ) \qquad Eq . 6.1$$

$${Y}_{t} = {h}_{0} ( {X}_{t} , {U}_{t} ) \qquad Eq . 6.2$$

### Where:

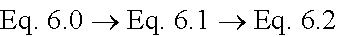

The functions (g₀) and (h₀) represent functions used by the state closure framework 600, where (g₀) represents the state-transition model 605 and (h₀) represents the observation model 610. The function NN represents the neural network 615 and a corrective model 620. Equation 6.1 represents function (g₀) producing an output of a latent state (Xₜ) 606 of the state-transition model 605. The Equation 6.2 represents function (h₀) producing the final output (Yₜ) 621 using the latent state (Xₜ) 606 as an input. Equation 6.0 represents function (NN) with the corrective model 620 producing an output model parameter (θₜ) 603 input into the function (g₀) of equation 6.1.

Exogenous input(s) (Uₜ) 601 represent inputs at discrete time step (t). The exogenous input(s) (Uₜ) 601 may correspond with the data obtained at 109 of FIG. 1 or it may correspond with data received via the query 103 of FIG. 1. Function (g₀) with model parameters (θ) 603 represents the evolution of the latent state 606 (\hat{X}ₜ) over time under the influence of the exogenous input(s) (Uₜ) 601 but without any additions. The prior state input(s) (Xₜ₋₁) 602 represents a prior state of the state-transition model 605 at discrete time step (t-1). The prior state input(s) (Xₜ₋₁) 602 is input into the function (g₀) to generate the state-transition model 605 latent state (\hat{X}ₜ) 606. The prior state input(s) (Xₜ₋₁) 602 may correspond with the system model obtained at 108 of FIG. 1 or with data received via the query 103 of FIG. 1.

The latent state (\hat{X}ₜ) 606 is input into the neural network 615 as represented by the function (NN). The neural function (NN) takes as inputs the latent state (\hat{X}ₜ) 606 as well as the exogenous input(s) (Uₜ) 601. The neural network 615 then produces an output based on the function (NN).

In the state closure framework 600, the latent state 606 (\hat{X}ₜ) output of the state-transition model 605 is input into the neural network 615, which in turn produces an output to the corrective model 620 which adds the output of the neural network to the prior state input(s) (Xₜ₋₁) 602. The corrective model 620 then generates a corrected latent state (Xₜ) 608 that is used as an input to the observation model 610 as represented by the function (h₀). The observation model 510 then generates the output (Yₜ) 511 from the input of the corrected latent state (Xₜ) 608.

The adding of the prior state input(s) (Xₜ₋₁) 602 which represents a prior state to the output of the neural network 615 allows the outputted corrected latent state to learn the residual in the latent state. This is particularly useful if it is easier for the neural network 615 to learn the residual than the states themselves.

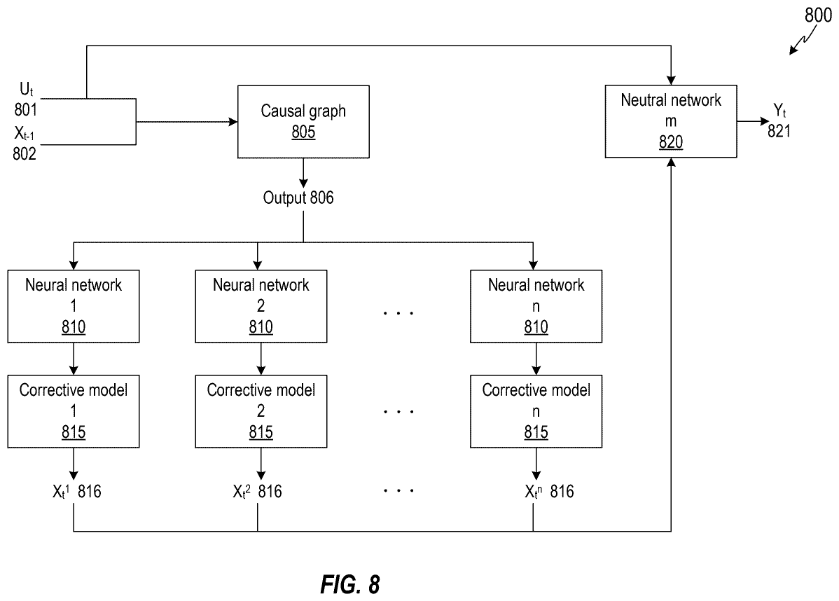

FIG. 7 depicts an example architecture of an output closure framework 700 for one aspect of a hybrid model. The output closure framework 700 may correspond to the output closure framework 308 of FIG. 3. The output closure framework 700 comprises a number (n) of low fidelity model(s) 705, a first neural network 710, a corrective model 715, and a second neural network 720. Each of the neural networks 710 and 720 may represent any deep neural network that maps a real vector to another vector of possibly different length. The output closure framework 700 may be applied to realized models, e.g., the realized model 304 of FIG. 3. In some aspects, more than the two neural networks 710 and 720 may be included in the output closure framework 700. The final output (Yₜ) 721 generated by output closure framework 700 may represent an underlying data generating system, e.g., a state of a system of interest being modeled by the hybrid model.

The low fidelity model(s) 705 represent system models (e.g., mechanistic models) of low fidelity. In some aspects, each of the low fidelity model(s) 705 may represent a different feature of a system. The output closure framework 700 may be represented by the following equations:

$${X}_{t} = {X}_{t - 1 +} N {N}_{1} ( {X}_{t - 1} , {U}_{t} , Y {(}_{t}^{0} ) , Y {(}_{t}^{1} ) , … , Y {(}_{t}^{n} ) ) \qquad Eq . 7.$$

$${Y}_{t} = N {N}_{2} ( {X}_{t} , {U}_{t} , Y {(}_{t}^{0} ) , Y {(}_{t}^{1} ) , … , Y {(}_{t}^{n} ) ) ) \qquad Eq . 7.1$$

### Where:

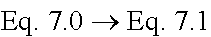

The function (NN₁) represents the first neural network 710, while the function (NN₂) represents the second neural network 720. Equation 7.0 represents producing a corrected latent state (Xₜ) 716 as an output by using the function (NN₁) along with the corrective model 715. Equation 7.1 uses the corrected latent state (Xₜ) 716 from equation 7.0 as input to generate the final output (Yₜ) 721 via the function (NN₂).

Exogenous input(s) (Uₜ) 701 represent inputs at discrete time step (t). The exogenous input(s) (Uₜ) 701 may correspond with the data obtained at 109 of FIG. 1 or may correspond with data received via the query 103 of FIG. 1. Prior state input(s) (Xₜ₋₁) 702 represents a prior state of the system at discrete time step (t-1). The prior state input(s) (Xₜ₋₁) 702 may correspond with the system model obtained at 108 of FIG. 1 or with data received via the query 103 of FIG. 1.

The exogenous input(s) (Uₜ) 701 and the prior state input(s) (Xₜ₋₁) 702 are input into the low fidelity model(s) 705 to generate outputs (Yₙ^{t}) 706 for each low fidelity model. The low fidelity model(s) 705 also consider model parameters (θ) 703 to produce the outputs (Yₙ^{t}) 706 where (n) represents the fidelity model of the low fidelity model(s) 705 and t represents a time step. The outputs (Yₙ^{t}) 706 represent an output of the k^{th} system (e.g., mechanistic) model at time (t). The outputs (Yₙ^{t}) 706 from the low fidelity model(s) 705 are input into the first neural network 710.

Parameters (θ) 711 are output by the first neural network 710 and are input into a corrective model 715 to be generate a corrected latent state (Xₜ) 716. The corrective model 715 adds the parameters (θ) 711 of the first neural network 710 to the prior state input(s) (Xₜ₋₁) 702 and generates corrected latent state (Xₜ) 716.

The corrected latent state (Xₜ) 716 is input into the second neural network 720 as represented by the function (NN₂). The neural function (NN₂) takes as inputs the corrected latent state (Xₜ) 716, the exogenous input(s) (Uₜ) 601, as well as the outputs (Yₙ^{t}) 706 from the low fidelity model(s) 705. The neural function (NN₂) generates the final output (Yₜ) 721.

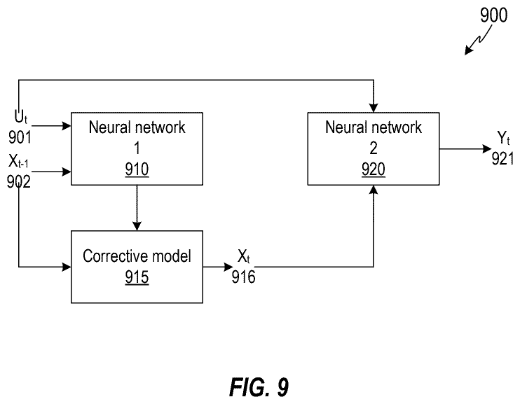

FIG. 8 depicts an example architecture of mechanistic neural ordinary differential equations 800 (mechanistic neural ODE 800) for one aspect of a hybrid model.

The mechanistic neural ODE 800 may correspond to the mechanistic neural ODE framework 311 of FIG. 3. The mechanistic neural ODE 800 comprises a causal graph 805, e.g., a directed acyclic graph (DAG), a number (n) of first neural networks(s) 810, a number (n) of corresponding corrective models 815, and a second neural network 820. The neural networks 810 and 820 may represent any deep neural network that maps a real vector to another vector of possibly different length. The mechanistic neural ODE 800 may be applied to causal graph models, e.g., the causal graph model 306 of FIG. 3. The final output (Yₜ) 821 generated by the mechanistic neural ODE 800 may represent an underlying data generating system, e.g., a state of a system of interest being modeled by the hybrid model.

The mechanistic neural ODE 800 may be represented by the following equations:

$${X}_{t}^{1} = {X}_{t 1}^{1} + N {N}_{1} ( {X}^{p {a ( i )}_{t 1}} , {U}^{p {a ( i )}_{t 1}} ) \qquad Eq . 8.$$

$${Y}_{t} = NN ( {X}_{t} \cdot {U}_{t} ) \qquad Eq . 8.1$$

### Where:

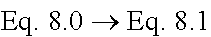

The neural network(s) 810 are each represented by the function (NNᵢ), while the neural network 820 is represented by the function (NN). The equation 8.0 produces an output of a corrected latent state (Xᵢ^{t}) 816 from each of the neural network(s) 810 and its corresponding corrective model 815. The equation 8.1 uses the combined outputs of the equations 8.0 of the various neural network(s) 810 and their respective corrective model(s) 815 as an input to produce the final output (Yₜ) 821.

The aim of the mechanistic neural ODE 800 is to encode causal structure into neural networks 810 and 820 so that the model as a whole learns evolution of particular states based on prior states in the causal graph. This may help prevent over-fitting and improve robustness of the model. The causal graph 805 represents system model(s) (e.g., mechanistic models). The causal graph 805 receives the exogenous input(s) (Uₜ) 801 that represent inputs at discrete time step (t). The causal graph 805 also receives the prior state input(s) (Xₜ₋₁) 802 that represent a prior state of the system at discrete time step (t-1). Exogenous input(s) (Uₜ) 801 represent inputs at discrete time step (t). Prior state input(s) (Xₜ₋₁) 802 represents a prior state of the system at discrete time step (t-1). The exogenous input(s) (Uₜ) 801 or may correspond with the data obtained at 109 of FIG. 1 or it may correspond with data received via the query 103 of FIG. 1. The prior state input(s) (Xₜ₋₁) 802 may correspond with the system model obtained at 108 of FIG. 1 or with data received via the query 103 of FIG. 1. The exogenous input(s) (Uₜ) 801 and the prior state input(s) (Xₜ₋₁) 802 are input into the causal graph 805 to generate an output 806. The output 806 is then input into each of the neural network(s) 810. The neural network(s) 810 are each represented by the function (NNᵢ) where (i) represents a specific neural network of the neural network(s) 810. The function (NNᵢ) also includes the variable (pa(i)) which represents the parents of the stat variable (i) in the causal graph.

The output of each of the neural network(s) 810 as represented by the function (NNᵢ) is input into a corresponding corrective model 815. Each of the corrective model(s) 815 adds the prior state input(s) (Xₜ₋₁) 802 to the output of the corresponding neural network 810 to generate a representation of a corrected latent state (Xᵢ^{t}) 816.

In some aspects, the corrected latent states (Xᵢ^{t}) 816 from each of the corrective model(s) 815 are added together and inputs these together as latent state (Xₜ) into the neural network 820. The neural network 820 is represented by the function (NN). The neural network 820 also obtains as input the exogenous input(s) (Uₜ) 801, and generates the final output (Yₜ) 821.

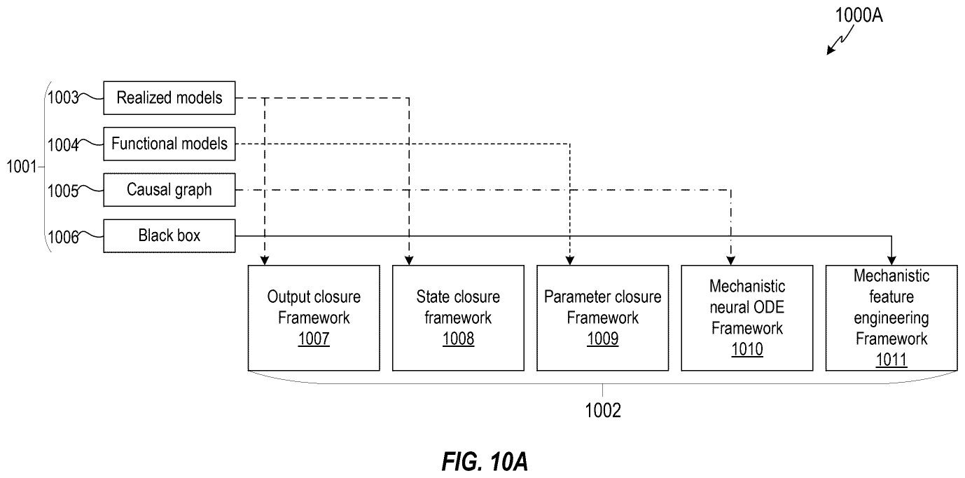

FIG. 9 depicts an example black-box neural ODE framework 900 for one aspect of a hybrid model. The black-box neural ODE 900 implements a state-space model, e.g., the state-space model 400 of FIG. 4, by using a recurrent neural network containing a custom recurrent cell encapsulating the functions (g) and (h) of the state-space model 400 of FIG. 4. A custom recurrent cell is a unit within a neural network such as a recurrent neural network (RNN) designed to achieve certain tasks. A custom recurrent cell allows for modifications in its structure, e.g., by changing activation functions or adjusting the number of gates.

The black-box neural ODE 900 may correspond to the mechanistic feature engineering framework 312 of FIG. 3. The black-box neural ODE 900 may be utilized when a black box system model is available, e.g., the black box model 307 of FIG. 3. For example, in aspects where no information about the underlying system apart from awareness of the state of variables is available, the system could be modeled by using a neural network to learn and represent the state-transition and observation models as represented by the functions (g) and (h) of FIG. 4. The advantages of this model is that it could provide additional flexibility to model more complex functions to represent state-transition and observation models using back-propagation learning techniques.

The black-box neural ODE 900 comprises a first neural network 910, a second neural network 920, and a corrective model 915. The neural networks 910 and 920 may represent any deep neural network that maps a real vector to another vector of possibly different length. The black-box neural ODE 900 may be applied to black box models, e.g., the black box model 307 of FIG. 3. The final output (Yₜ) 921 generated by the black-box neural ODE 900 may represent an underlying data generating system, e.g., a state of a system of interest being modeled by the hybrid model. The black-box neural ODE 900 may be represented by the following equations:

$${X}_{t} = {X}_{t - 1} + N N ( {U}_{t} , {X}_{t - 1} ) \qquad Eq . 9.$$

$${Y}_{t} = N N ( {X}_{t} \cdot {U}_{t} ) \qquad Eq . 9.1$$

### Where:

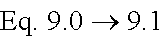

Equation 9.0 represents the first neural network 910 with function (NN). Equation 9.1 represents the second neural network 920 with the function (NN) as well. However, the equation 9.0 along with the corrective model generates an output of latent state (Xₜ) 916 that is input into the function (NN) of the equation 9.1 to generate the final output (Yₜ) 921.

The first neural network 910 receives exogenous input(s) (Uₜ) 901 that represent inputs at discrete time step (t). The first neural network 910 also receives the prior state input(s) (Xₜ₋₁) 902 that represent a prior state of the system at discrete time step (t-1). Exogenous input(s) (Uₜ) 901 represent inputs at discrete time step (t). Prior state input(s) (Xₜ₋₁) 902 represents a prior state of the system at discrete time step (t-1). The exogenous input(s) (Uₜ) 901 or may correspond with the data obtained at 109 of FIG. 1 or it may correspond with data received via the query 103 of FIG. 1. The prior state input(s) (Xₜ₋₁) 902 may correspond with the system model obtained at 108 of FIG. 1 or with data received via the query 103 of FIG. 1. The exogenous input(s) (Uₜ) 901 and the prior state input(s) (Xₜ₋₁) 902 are input into the first neural network 910 as represented by the function (NN) to generate an output that is then added to the prior state input(s) (Xₜ₋₁) 902 by the corrective model 915 to generate an output representing the latent state (Xₜ) 916.

The latent state (Xₜ) 916 is then input into the second neural network 920 which uses it along with exogenous input(s) (Uₜ) 901 to produce the final output (Yₜ) 921.

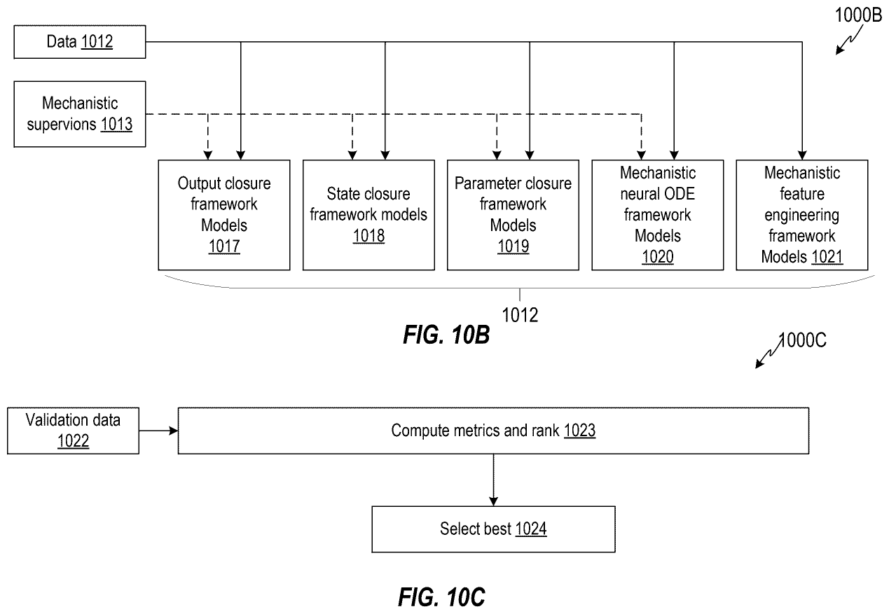

FIG. 10A depicts another example triage process 1000A of the hybrid modeling tool. The example triage process 1000A may combine with example processes 1000B and 1000C of FIGS. 10B and 10C, respectively, to autonomously generate hybrid model(s). In some aspects, the processes 1000A-1000C of FIGS. 10A-10C in combination may correspond with the modeling tool process 101 of FIG. 1.

In some aspects, the example triage process 1000A comprises a set of system models 1001. The set of system models 1001 may include realized models, functional models, causal graph models and black box models (listed in order of lowest abstraction to highest abstraction). The set of system models 1001 may correspond to the set of system models 301 of FIG. 3.

In some aspects, the example triage process 1000A comprises a set of framework(s) 1002 for the generating of hybrid model(s). The set of framework(s) 1002 may include an output closure framework, a state closure framework, a parameter closure framework, a mechanistic neural ODE framework, and a mechanistic feature engineering framework. The set of framework(s) 1002 may correspond to the framework(s) 302 of FIG. 3, or the listed framework(s) in column 201 of FIG. 2. For example, implementation of a framework of the set of framework(s) 1002 generate hybrid model(s).

In the example triage process 1000A, if a modeling tool, e.g., the modeling tool 150 of FIG. 1, obtains one or more of the set of system models 1001, it may use the availability of these models to determine the framework(s) that may be used to generate framework(s) 1002. The obtaining of the models may correspond with the obtaining of a system model at 108, of FIG. 1. In some aspects, the obtaining of these system models may correspond to the obtaining of the data received at 109 of FIG. 1, or may correspond to data received from the user 102, e.g., via the query 103 of FIG. 1.

In some aspects, given the availability of one type of system model, the modeling tool can also derive models of higher abstraction. For example if a causal graph model(s) 1005 is available, the modeling tool can generate black box model(s) 1006 (and consequently use the framework(s) 1002 for the black box model(s) 1006). In some aspects, the availability of realized system model(s) 1003 allows the modeling tool to utilize an output closure framework 1007, e.g., as described by the output closure framework 700 of FIG. 7. In relation to FIGS. 10A-10C, the modeling tool may also utilize a state closure framework 1008, e.g., as described by the state closure framework 600 of FIG. 6. The availability of functional model(s) 1004 allows the modeling tool to utilize the parameter closure framework 1009, e.g., as described by the parameter closure framework 500 of FIG. 5. The availability of causal graph model(s) 1005 allows the modeling tool to utilize the mechanistic neural ODE framework 1010, e.g., as described by the mechanistic neural ODE 800 of FIG. 8. The availability of a black box model(s) 1006 allows the modeling tool to utilize a mechanistic feature engineering framework 1011, e.g., as described by the black-box neural ODE 900 of FIG. 9.

FIG. 10B depicts an example training process 1000B for hybrid modeling by the hybrid modeling tool. The example training process 1000B may continue from the example triage process 1000A of FIG. 10A.

Each of the frameworks described in the framework(s) 1002 of FIG. 10A (example frameworks) may comprise one or more models (respective models 1017-1021). The models 1017-1021 may correspond with any of the models described in the example architectures 400-900 of FIGS. 4-9. The combination of different models in the example frameworks provides hybrid modeling (also described as a hybrid model). For example, the models in these example frameworks may include observation models, state-space models, neural networks, corrective models, and the like. The output closure framework 1007 may comprise models 1017, the state closure framework 1008 may comprise models 1018, the parameter closure framework may comprise models 1019, the mechanistic neural ODE framework 1010 may comprise models 1020, and the mechanistic feature engineering framework 1011 may comprise models 1021.

The training of these models of the example frameworks may occur as described in relation to the frameworks 400-900 of FIGS. 4-9. Training may occur with input data 1012 that may correspond with any input data described in relation to the frameworks 400-900 of FIGS. 4-9. Some input data into one model (of the models 1017-1021) may for example be output data of another model. The example training process 1000B may also include mechanistic supervision 1013 (which may correspond with the mechanistic supervision 303 of FIG. 3), where a system model (e.g., a state transition model) may supervise or input parameters into a neural network to reinforce or adjust its learning. However, in some aspects, the mechanistic feature engineering framework 1011 may not utilize a system model such as a state-space model to supervise the neural network but may rely on a corrective model instead to train the neural network(s) (e.g., the corrective model 915 of FIG. 9).

FIG. 10C depicts an example model ranking process 1000C for hybrid modeling by the hybrid modeling tool. The example model ranking process 1000C may continue from the processes 1000A or 1000B of FIGS. 10A-10B.

For example, if an underlying system being modeled has realized models, causal graph models, functional models, or blackbox models, then the modeling tool may compare all the different available models and their associated framework(s) to determine which framework produces the most accurate results. This may be based on predetermined benchmarks.

Validation data 1022 that may be produced by the example training process 1000B of FIG. 10B may be used for computing metrics of each model produced by each of the frameworks 1007-1012 in FIG. 10A. The validation data may be produced in a manner corresponding to 115 of FIG. 1, which may include tuning any of the models 1017-1021.

The validation data is then processed to compute metrics and ranking of the models at 1023. Computations of the validation data 1022 may include determination of performance metrics (that may include statistical analysis). The determination of performance metrics may include generating one or more of mean absolute error (MAE), Absolute error (AE), peak absolute error (PAE), mean absolute percentage error (MAPE), root mean squared error (RMSE), and correlation for the results generated by each of the models 1017-1021. The various models may be ranked based on these statistical comparisons. The modeling tool, e.g., the modeling tool 150 of FIG. 1, selects 1024 the best performing hybrid model 1017-1021 (or a hybrid model based on any other predefined selection or criteria) for the system.

### Example Method for Hybrid Modeling a System of Interest

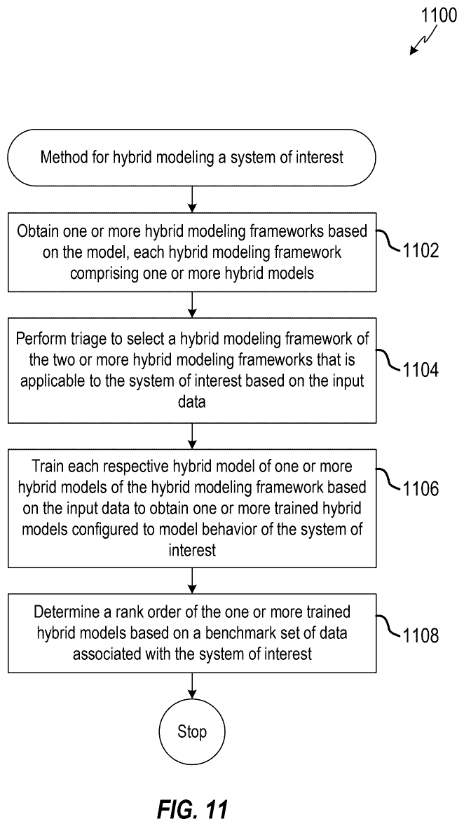

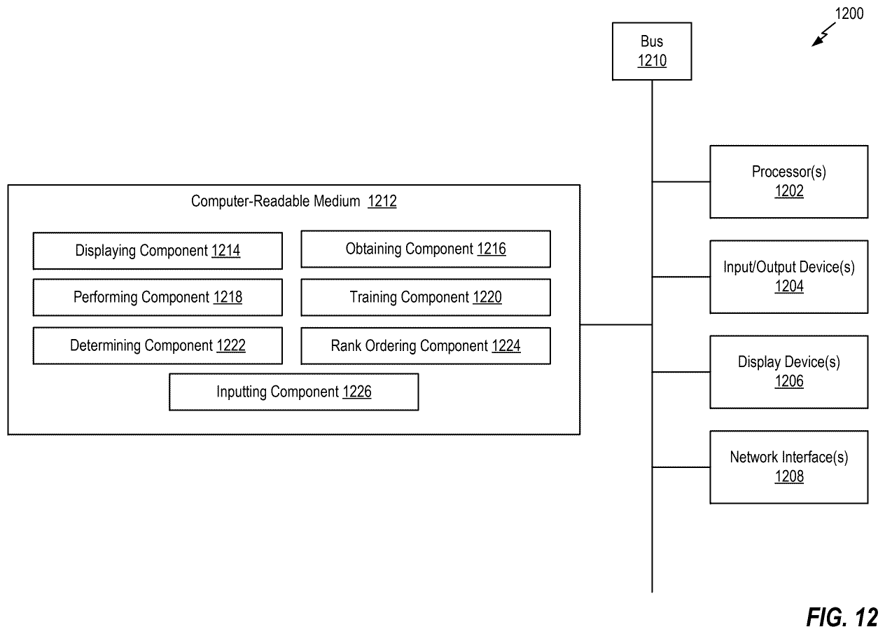

FIG. 11 shows a method 1100 for hybrid modeling a system of interest. In one aspect, method 1100 may be performed by a processing system, such as a processing system 1200 described with reference to FIG. 12.

Method 1100 begins at block 1102 with obtaining one or more hybrid modeling frameworks based on the model, each hybrid modeling framework comprising one or more hybrid models.

Method 1100 then proceeds to block 1104 with performing triage to select a hybrid modeling framework of the one or more hybrid modeling frameworks that is applicable to the system of interest based on associated metrics and the input data.

Method 1100 then proceeds to block 1106 with training each respective hybrid model of the one or more hybrid models of the hybrid modeling framework based on the input data to obtain one or more trained hybrid models configured to model behavior of the system of interest.

Method 1100 then proceeds to block 1108 with determining a rank order of the one or more trained hybrid models based on a benchmark set of data associated with the system of interest.

In some aspects, the method 1100 includes displaying a user interface on a display device that enables a user to input data associated with a system of interest and select a model associated with the system of interest.

In some aspects, the method 1100 includes displaying the one or more trained hybrid models and corresponding rank in the user interface on the display device.

In some aspects, the user interface enables the user to select and run a trained hybrid model that is configured to model behavior of the system of interest.

In some aspects, each hybrid model of one or more hybrid models comprises a physics-based model and a data-driven model.

In some aspects, block 1104 includes: obtaining an output closure framework and a state closure framework when the model selected by the user is a realized model; obtaining an output closure framework, a state closure framework, and a parameter closure framework when the model selected by the user is a functional model; obtaining an output closure framework, a state closure framework, a parameter closure framework, and a mechanistic neural ODE when the model selected by the user is a causal graph; or obtaining an output closure framework, a state closure framework, a parameter closure framework, a mechanistic neural ODE, and a mechanistic feature engineering framework when the model selected by the user is a black box.

In some aspects, block 1108 includes at least one of: performing parameter closure learning on the respective hybrid model to obtain a parameter closure model applicable to the system of interest; performing state closure learning on the respective hybrid model to obtain a state closure model applicable to the system of interest; performing output closure learning on the respective hybrid model to obtain an output closure model applicable to the system of interest; performing mechanistic neural ODE learning on the respective hybrid model to obtain a mechanistic neural ODE model applicable to the system of interest; and performing black-box neural ODE learning on the respective hybrid model to obtain a black-box neural ODE model applicable to the system of interest, wherein the parameter closure model, the state closure model, the output closure model, and the mechanistic neural ODE model are the trained hybrid models, and wherein training is performed using a loss function with one or more penalty terms configured to enforce mechanistic rules.

In some aspects, the parameter closure model comprises: a state transition model configured to receive as input a state value and an exogenous value and output a latent state value; a neural network configured to update parameters of the state transition model; and an observation model configured to receive as input the state value and output an observed value.

In some aspects, the state closure model comprises: a state transition model configured to receive a state value and an exogenous value and output a latent state value; a neural network configured to receive the state value and output an updated state value; and an observation model configured to receive the updated state value and output an observed value.

In some aspects, the state closure model comprises: a state transition model configured to receive a state value and an exogenous value and output an intermediate state value; a neural network configured to receive the intermediate state value and the exogenous value and output a parameter; a corrective model configured to receive the state value and the parameter and output a latent state value; and an observation model configured to receive the latent state value and the exogenous value and output an observed value.

In some aspects, the output closure model comprises: a low-fidelity model configured to receive a state value and an exogenous value and output an intermediate observed value; a first neural network configured to receive the state value, the exogenous value, and the intermediate observed value and output a parameter; an addition model configured to receive the state value and the parameter and output a latent state value; and a second neural network configured to receives the latent state value and output an observed value.

In some aspects, the mechanistic neural ODE model comprises: a causal graph configured to receive a state value and an exogenous value and outputs a causal value; a set of neural networks configured to receive the causal value and output a set of latent state values; and a neural network configured to receive the exogenous value and the set of latent state values and output an observed value.

In some aspects, the black-box neural ODE model comprises: a first neural network configured to receive a state value and an exogenous value and output a parameter; an additional model configured to receive the parameter and the state value and output a latent state value; and a second neural network configured to receive the latent state value and the exogenous value and output an observed value.

In some aspects, block 1110 includes inputting the input data to the respective trained hybrid model; obtaining, as output from the respective trained hybrid model, observed data; and determining an error associated with a trained hybrid model based on the observed data and ground truth data associated with the system of interest; and rank ordering the one or more trained hybrid models based on associated errors.

In some aspects, method 1100, or any aspect related to it, may be performed by an apparatus or a processing system, such as processing system 1200 of FIG. 12, which includes various components operable, configured, or adapted to perform the method 1100. Processing system 1200 is described below in further detail.

The method 1100 provides a process for autonomous hybrid model generation that may be applied to a wide range of systems, and which provides several technical benefits, such as beneficially reducing compute resource usage compared to generating hybrid models manually. The triage process to select the framework(s) reduces the amount of testing that may be expended and reduces computational resources dedicated for simulations and evaluations. Furthermore, pre-designed model combinations may be based on specific hybrid modeling framework(s). These model combinations are known to be integrate well with each other, reducing any processing or computations to determine integration of models. The use of the method 1100, which may be a unified modeling process to build and test hybrid models reduces overhead from data transfers or data transformations between different software packages or tools. A unified modeling tool therefore simplifies the process and reduces computational time and computational resources in generating hybrid models.

Note that FIG. 11 is just one example of a method, and other methods including fewer, additional, or alternative operations are possible consistent with this disclosure.

### Example Processing System for a Hybrid Modeling Tool

FIG. 12 depicts an example processing system 1200 configured to perform various aspects described herein, including, for example, method 1100 as described above with respect to FIG. 11.

Processing system 1200 is generally an example of an electronic device configured to execute computer-executable instructions, such as those derived from compiled computer code, including without limitation personal computers, tablet computers, servers, smart phones, smart devices, wearable devices, augmented and/or virtual reality devices, and others.

In the depicted example, processing system 1200 includes one or more processor(s) 1202, one or more input/output device(s) 1204, one or more display device(s) 1206, one or more network interface(s) 1208 through which processing system 1200 is connected to one or more networks (e.g., a local network, an intranet, the Internet, or any other group of processing systems communicatively connected to each other), and computer-readable medium 1212. In the depicted example, the aforementioned components are coupled by a bus 1210, which may generally be configured for data exchange amongst the components. Bus 1210 may be representative of multiple buses, while only one is depicted for simplicity.

Processor(s) 1202 are generally configured to retrieve and execute instructions stored in one or more memories, including local memories like computer-readable medium 1212, as well as remote memories and data stores. Similarly, processor(s) 1202 are configured to store application data residing in local memories like the computer-readable medium 1212, as well as remote memories and data stores. More generally, bus 1210 is configured to transmit programming instructions and application data among the processor(s) 1202, display device(s) 1206, network interface(s) 1208, and/or computer-readable medium 1212. In certain embodiments, processor(s) 1202 are representative of a one or more central processing units (CPUs), graphics processing unit (GPUs), tensor processing unit (TPUs), accelerators, and other processing devices.

Input/output device(s) 1204 may include any device, mechanism, system, interactive display, and/or various other hardware and software components for communicating information between processing system 1200 and a user of processing system 1200. For example, input/output device(s) 1204 may include input hardware, such as a keyboard, touch screen, button, microphone, speaker, and/or other device for receiving inputs from the user and sending outputs to the user.

Display device(s) 1206 may generally include any sort of device configured to display data, information, graphics, user interface elements, and the like to a user. For example, display device(s) 1206 may include internal and external displays such as an internal display of a tablet computer or an external display for a server computer or a projector. Display device(s) 1206 may further include displays for devices, such as augmented, virtual, and/or extended reality devices. In various embodiments, display device(s) 1206 may be configured to display a graphical user interface.

Network interface(s) 1208 provide processing system 1200 with access to external networks and thereby to external processing systems. The network interface(s) 1208 can generally be any hardware and/or software capable of transmitting and/or receiving data via a wired or wireless network connection. Accordingly, network interface(s) 1208 can include a communication transceiver for sending and/or receiving any wired and/or wireless communication.

Computer-readable medium 1212 may be a volatile memory, such as a random access memory (RAM), or a nonvolatile memory, such as nonvolatile random access memory (NVRAM), or the like. In this example, computer-readable medium 1212 includes displaying component 1214, obtaining component 1216, performing component 1218 is configured to training component 1220, determining component 1222, rank ordering component 1224, and inputting component 1226.

In certain embodiments, displaying component 1214 is configured to display a user interface on a display device that enables a user to input data associated with a system of interest and select a model associated with the system of interest, as described in FIG. 11 with reference to block 1102.

In certain embodiments, obtaining component 1216 is configured to obtain one or more hybrid modeling frameworks based on the model, each hybrid modeling framework comprising one or more hybrid models, as described in FIG. 11 with reference to block 1104.

In certain embodiments, performing component 1218 is configured to perform triage to select a hybrid modeling framework of the one or more hybrid modeling frameworks that is applicable to the system of interest based on associated metrics and the input data, as described in FIG. 11 with reference to block 1106.

In certain embodiments, training component 1220 is configured to train each respective hybrid model of the one or more hybrid models of the hybrid modeling framework based on the input data to obtain one or more trained hybrid models configured to model behavior of the system of interest, as described in FIG. 11 with reference to block 1108.

In certain embodiments, determining component 1222 is configured to determine a rank order of the one or more trained hybrid models based on a benchmark set of data associated with the system of interest, as described in FIG. 11 with reference to block 1110.

In certain embodiments, displaying component 1214 is configured to display the one or more trained hybrid models and corresponding rank in the user interface on the display device, as described in FIG. 11 with reference to block 1112.

Note that FIG. 12 is just one example of a processing system consistent with aspects described herein, and other processing systems having additional, alternative, or fewer components are possible consistent with this disclosure.

### Example Clauses

Implementation examples are described in the following numbered clauses:
Clause 1: A method, comprising: obtaining one or more hybrid modeling frameworks based on the model, each hybrid modeling framework comprising one or more hybrid models; performing triage to select a hybrid modeling framework of the one or more hybrid modeling frameworks that is applicable to the system of interest based on associated metrics and the input data; training each respective hybrid model of the one or more hybrid models of the hybrid modeling framework based on the input data to obtain one or more trained hybrid models configured to model behavior of the system of interest; and determining a rank order of the one or more trained hybrid models based on a benchmark set of data associated with the system of interest.
Clause 2: The method of Clause 1, further comprising: displaying a user interface on a display device that enables a user to input data associated with a system of interest and select a model associated with the system of interest.
Clause 3: The method of any of Clauses 1-2, further comprising: displaying the one or more trained hybrid models and corresponding rank in the user interface on the display device.
Clause 4: The method of any one of Clauses 1-3, wherein the user interface enables the user to select and run a trained hybrid model that is configured to model behavior of the system of interest.
Clause 5: The method of any one of Clauses 1-4, wherein each hybrid model of one or more hybrid models comprises a physics-based model and a data-driven model.
Clause 6: The method of any one of Clauses 1-5, wherein the obtaining of the one or more hybrid modeling frameworks based on the model comprises: obtaining an output closure framework and a state closure framework when the model selected by the user is a realized model; obtaining an output closure framework, a state closure framework, and a parameter closure framework when the model selected by the user is a functional model; obtaining an output closure framework, a state closure framework, a parameter closure framework, and a mechanistic neural ODE when the model selected by the user is a causal graph; or obtaining an output closure framework, a state closure framework, a parameter closure framework, a mechanistic neural ODE, and a mechanistic feature engineering framework when the model selected by the user is a black box.
Clause 7: The method of any one of Clauses 1-6, wherein training each respective hybrid model of the one or more hybrid models comprises at least one of: performing parameter closure learning on the respective hybrid model to obtain a parameter closure model applicable to the system of interest; performing state closure learning on the respective hybrid model to obtain a state closure model applicable to the system of interest; performing output closure learning on the respective hybrid model to obtain an output closure model applicable to the system of interest; performing mechanistic neural ODE learning on the respective hybrid model to obtain a mechanistic neural ODE model applicable to the system of interest; and performing black-box neural ODE learning on the respective hybrid model to obtain a black-box neural ODE model applicable to the system of interest, wherein the parameter closure model, the state closure model, the output closure model, and the mechanistic neural ODE model are the trained hybrid models, and wherein training is performed using a loss function with one or more penalty terms configured to enforce mechanistic rules.
Clause 8: The method of any one of Clauses 1-7, wherein the parameter closure model comprises: a state transition model configured to receive as input a state value and an exogenous value and output a latent state value; a neural network configured to update parameters of the state transition model; and an observation model configured to receive as input the state value and output an observed value.
Clause 9: The method of any one of Clauses 1-8, wherein the state closure model comprises: a state transition model configured to receive a state value and an exogenous value and output a latent state value; a neural network configured to receive the state value and output a updated state value; and an observation model configured to receive the updated state value and output an observed value.
Clause 10: The method of any one of Clauses 1-9, wherein the state closure model comprises: a state transition model configured to receive a state value and an exogenous value and output an intermediate state value; a neural network configured to receive the intermediate state value and the exogenous value and output a parameter; a corrective model configured to receive the state value and the parameter and output a latent state value; and an observation model configured to receive the latent state value and the exogenous value and output an observed value.
Clause 11: The method of any one of Clauses 1-10, wherein the output closure model comprises: a low-fidelity model configured to receive a state value and an exogenous value and output an intermediate observed value; a first neural network configured to receive the state value, the exogenous value, and the intermediate observed value and output a parameter; an addition model configured to receive the state value and the parameter and output a latent state value; and a second neural network configured to receives the latent state value and output an observed value.
Clause 12: The method of any one of Clauses 1-11, wherein the mechanistic neural ODE model comprises: a causal graph configured to receive a state value and an exogenous value and outputs a causal value; a set of neural networks configured to receive the causal value and output a set of latent state values; and a neural network configured to receive the exogenous value and the set of latent state values and output an observed value.
Clause 13: The method of any one of Clauses 1-12, wherein the black-box neural ODE model comprises: a first neural network configured to receive a state value and an exogenous value and output a parameter; an additional model configured to receive the parameter and the state value and output a latent state value; and a second neural network configured to receive the latent state value and the exogenous value and output an observed value.
Clause 14: The method of any one of Clauses 1-13, wherein determining the rank order of the one or more trained hybrid models for each respective trained hybrid model to the one or more trained hybrid models comprises: inputting the input data to the respective trained hybrid model; obtaining, as output from the respective trained hybrid model, observed data; and determining an error associated with a trained hybrid model based on the observed data and ground truth data associated with the system of interest; and rank ordering the one or more trained hybrid models based on associated errors.
Clause 15: One or more processing systems, comprising: one or more memories comprising computer-executable instructions; and one or more processors configured to execute the computer-executable instructions and cause the one or more processing systems to perform a method in accordance with any one of Clauses 1-14.
Clause 16: One or more processing systems, comprising means for performing a method in accordance with any one of Clauses 1-14.
Clause 17: One or more non-transitory computer-readable media comprising instructions that, when executed by one or more processors of a computing system, cause the computing system to perform the operations of any one of Clauses 1-14.
Clause 18: One or more computer program products embodied on one or more computer-readable storage media comprising code for performing a method in accordance with any one of Clauses 1-14.

### Additional Considerations

The preceding description is provided to enable any person skilled in the art to practice the various embodiments described herein. The examples discussed herein are not limiting of the scope, applicability, or embodiments set forth in the claims. Various modifications to these embodiments will be readily apparent to those skilled in the art, and the generic principles defined herein may be applied to other embodiments. For example, changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method that is practiced using other structure, functionality, or structure and functionality in addition to, or other than, the various aspects of the disclosure set forth herein. It should be understood that any aspect of the disclosure disclosed herein may be embodied by one or more elements of a claim.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

As used herein, the term “determining” encompasses a wide variety of actions. For example, “determining” may include calculating, computing, processing, deriving, investigating, looking up (e.g., looking up in a table, a database or another data structure), ascertaining and the like. Also, “determining” may include receiving (e.g., receiving information), accessing (e.g., accessing data in a memory) and the like. Also, “determining” may include resolving, selecting, choosing, establishing and the like.

As used herein, unless stated otherwise, the term “or” is used in an inclusive sense. This inclusive usage of or is equivalent to “and/or”. Thus, when options are delineated using “or,” it permits the selection of one or more of the enumerated options concurrently. For example, if the document stipulates that a component may comprise option A or option B, it shall be understood to mean that the component may comprise option A, option B, or both option A and option B, and does not mean, unless stated expressly that the component includes either option A or option B. This inclusive interpretation ensures that all potential combinations of the options are permissible, rather than restricting the choice to a singular, exclusive option.

The methods disclosed herein comprise one or more steps or actions for achieving the methods. The method steps and/or actions may be interchanged with one another without departing from the scope of the claims. In other words, unless a specific order of steps or actions is specified, the order and/or use of specific steps and/or actions may be modified without departing from the scope of the claims. Further, the various operations of methods described above may be performed by any suitable means capable of performing the corresponding functions. The means may include various hardware and/or software component(s) and/or module(s), including, but not limited to a circuit, an application specific integrated circuit (ASIC), or processor. Generally, where there are operations illustrated in figures, those operations may have corresponding counterpart means-plus-function components with similar numbering.

The following claims are not intended to be limited to the embodiments shown herein, but are to be accorded the full scope consistent with the language of the claims. Within a claim, reference to an element in the singular is not intended to mean “one and only one” unless specifically so stated, but rather “one or more.” Unless specifically stated otherwise, the term “some” refers to one or more. No claim element is to be construed under the provisions of 35 U.S.C. § 112(f) unless the element is expressly recited using the phrase “means for” or, in the case of a method claim, the element is recited using the phrase “step for.” All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims.

What is claimed is:

1. A method, comprising:
obtaining one or more hybrid modeling frameworks based on a model associated with a system of interest, each hybrid modeling framework comprising one or more hybrid models;
performing triage to select a hybrid modeling framework of the one or more hybrid modeling frameworks that is applicable to the system of interest based on associated metrics and input data;
training each respective hybrid model of the one or more hybrid models of the hybrid modeling framework based on the input data to obtain one or more trained hybrid models configured to model behavior of the system of interest; and
determining a rank order of the one or more trained hybrid models based on a benchmark set of data associated with the system of interest.

2. The method of claim 1, further comprising:
displaying a user interface on a display device that enables a user to enter the input data associated with the system of interest and select the model associated with the system of interest; and
displaying the one or more trained hybrid models and corresponding rank in the user interface on the display device, wherein the user interface enables the user to select and run a trained hybrid model that is configured to model behavior of the system of interest.

3. The method of claim 1, wherein each hybrid model of one or more hybrid models comprises a physics-based model and a data-driven model.

4. The method of claim 1, wherein the obtaining of the one or more hybrid modeling frameworks based on the model comprises:
obtaining an output closure framework and a state closure framework when the model is a realized model;
obtaining an output closure framework, a state closure framework, and a parameter closure framework when the model is a functional model;
obtaining an output closure framework, a state closure framework, a parameter closure framework, and a mechanistic neural ordinary differential equation (ODE) when the model is a causal graph; or
obtaining an output closure framework, a state closure framework, a parameter closure framework, a mechanistic neural ODE, and a mechanistic feature engineering framework when the model is a black box.

5. The method of claim 1, wherein training each respective hybrid model of the one or more hybrid models comprises at least one of:
performing parameter closure learning on the respective hybrid model to obtain a parameter closure model applicable to the system of interest;
performing state closure learning on the respective hybrid model to obtain a state closure model applicable to the system of interest;
performing output closure learning on the respective hybrid model to obtain an output closure model applicable to the system of interest;
performing mechanistic neural ODE learning on the respective hybrid model to obtain a mechanistic neural ODE model applicable to the system of interest; and
performing black-box neural ODE learning on the respective hybrid model to obtain a black-box neural ODE model applicable to the system of interest,
wherein the parameter closure model, the state closure model, the output closure model, and the mechanistic neural ODE model are the trained hybrid models, and
wherein training is performed using a loss function with one or more penalty terms configured to enforce mechanistic rules.

6. The method of claim 5, wherein the parameter closure model comprises:
a state transition model configured to receive as input a state value and an exogenous value and output a latent state value;
a neural network configured to update parameters of the state transition model; and
an observation model configured to receive as input the state value and output an observed value.

7. The method of claim 5, wherein the state closure model comprises:
a state transition model configured to receive a state value and an exogenous value and output a latent state value;
a neural network configured to receive the state value and output a updated state value; and
an observation model configured to receive the updated state value and output an observed value.

8. The method of claim 5, wherein the state closure model comprises:
a state transition model configured to receive a state value and an exogenous value and output an intermediate state value;
a neural network configured to receive the intermediate state value and the exogenous value and output a parameter;
a corrective model configured to receive the state value and the parameter and output a latent state value; and
an observation model configured to receive the latent state value and the exogenous value and output an observed value.

9. The method of claim 5, wherein the output closure model comprises:
a low-fidelity model configured to receive a state value and an exogenous value and output an intermediate observed value;
a first neural network configured to receive the state value, the exogenous value, and the intermediate observed value and output a parameter;
an addition model configured to receive the state value and the parameter and output a latent state value; and
a second neural network configured to receives the latent state value and output an observed value.

10. The method of claim 5, wherein the mechanistic neural ODE model comprises:
a causal graph configured to receive a state value and an exogenous value and outputs a causal value;
a set of neural networks configured to receive the causal value and output a set of latent state values; and
a neural network configured to receive the exogenous value and the set of latent state values and output an observed value.

11. The method of claim 5, wherein the black-box neural ODE model comprises:
a first neural network configured to receive a state value and an exogenous value and output a parameter;
an additional model configured to receive the parameter and the state value and output a latent state value; and
a second neural network configured to receive the latent state value and the exogenous value and output an observed value.

12. The method of claim 1, wherein determining the rank order of the one or more trained hybrid models comprises:
for each respective trained hybrid model to the one or more trained hybrid models,
inputting the input data to the respective trained hybrid model;
obtaining, as output from the respective trained hybrid model, observed data; and
determining an error associated with a trained hybrid model based on the observed data and ground truth data associated with the system of interest; and
rank ordering the one or more trained hybrid models based on associated errors.

13. A processing system, comprising
a memory comprising computer-executable instructions; and
a processor configured to execute the computer-executable instructions and cause the processing system to:
obtain one or more hybrid modeling frameworks based on a model associated with a system of interest, each hybrid modeling framework comprising one or more hybrid models;
perform triage to select a hybrid modeling framework of the one or more hybrid modeling frameworks that is applicable to the system of interest based on associated metrics and input data;
train each respective hybrid model of one or more hybrid models of the hybrid modeling framework based on the input data to obtain one or more trained hybrid models configured to model behavior of the system of interest; and
determine a rank order of the one or more trained hybrid models based on a benchmark set of data associated with the system of interest.

14. The processing system of claim 13, wherein the processor is further configured to cause the processing system to:
display a user interface on a display device that enables a user to input data associated with the system of interest and a select the model; and
display the one or more trained hybrid models and corresponding rank in the user interface on the display device, wherein the user interface enables the user to select and run a trained hybrid model that is configured to model behavior of the system of interest.

15. The processing system of claim 13, wherein each hybrid model of one or more hybrid models comprises a physics-based model and a data-driven model.

16. The processing system of claim 13, wherein to obtain the one or more hybrid modeling frameworks, the processor is configured to cause the processing system to obtain at least one of:
an output closure framework and a state closure framework when the model is a realized model;
an output closure framework, a state closure framework, and a parameter closure framework when the model is a functional model;
an output closure framework, a state closure framework, a parameter closure framework, and a mechanistic neural ordinary differential equation (ODE) when the model is a causal graph; or
an output closure framework, a state closure framework, a parameter closure framework, a mechanistic neural ODE, and a mechanistic feature engineering framework when the model is a black box.

17. The processing system of claim 13, wherein to train each respective hybrid model of the one or more hybrid models, the processor is configured to cause the processing system to:
perform parameter closure learning on the respective hybrid model to obtain a parameter closure model applicable to the system of interest;
perform state closure learning on the respective hybrid model to obtain a state closure model applicable to the system of interest;
perform output closure learning on the respective hybrid model to obtain an output closure model applicable to the system of interest;
perform mechanistic neural ODE learning on the respective hybrid model to obtain a mechanistic neural ODE model applicable to the system of interest; and
perform black-box neural ODE learning on the respective hybrid model to obtain a black-box neural ODE model applicable to the system of interest,
wherein the parameter closure model, the state closure model, the output closure model, and the mechanistic neural ODE model are the trained hybrid models, and
wherein training is performed using a loss function with one or more penalty terms configured to enforce mechanistic rules.

18. The processing system of claim 13, wherein to determine the rank order of the one or more trained hybrid models, the processor is configured to cause the processing system for each respective trained hybrid model to:
input the input data to the respective trained hybrid model;
obtain, as output from the respective trained hybrid model, observed data; and
determine an error associated with a trained hybrid model based on the observed data and ground truth data associated with the system of interest; and
rank order the one or more trained hybrid models based on associated errors.

19. A non-transitory computer-readable medium comprising instructions that, when executed by one or more processors of a computing system, cause the computing system to perform operations for hybrid modeling a system of interest, the operations comprising:
obtaining one or more hybrid modeling frameworks based on a model associated with a system of interest, each hybrid modeling framework comprising one or more hybrid models;
performing triage to select a hybrid modeling framework of the one or more hybrid modeling frameworks that is applicable to the system of interest based on associated metrics and input data;
training each respective hybrid model of the one or more hybrid models of the hybrid modeling framework based on the input data to obtain one or more trained hybrid models configured to model behavior of the system of interest; and
determining a rank order of the one or more trained hybrid models based on a benchmark set of data associated with the system of interest.

20. The non-transitory computer-readable medium of claim 19, the operations further comprising displaying a user interface on a display device that enables a user to input data associated with the system of interest and select the model associated with the system of interest, wherein the obtaining of the one or more hybrid modeling frameworks based on the model comprises:
obtaining an output closure framework and a state closure framework when the model is a realized model;
obtaining an output closure framework, a state closure framework, and a parameter closure framework when the model is a functional model;
obtaining an output closure framework, a state closure framework, a parameter closure framework, and a mechanistic neural ordinary differential equation (ODE) when the model is a causal graph; or
obtaining an output closure framework, a state closure framework, a parameter closure framework, a mechanistic neural ODE, and a mechanistic feature engineering framework when the model is a black box.
